(19) United States
(12) Patent Application Publication
(10) Pub. No.: US 2013/0029472 A1
(43) Pub. Date: Jan. 31, 2013

(54) GaN BONDED SUBSTRATE AND METHOD OF MANUFACTURING GaN BONDED SUBSTRATE

(71) Applicants: BONGMO PARK, ChungCheongNam-Do (KR); Kwang Je Woo, ChungCheongNam-Do (KR); Jun Sung Choi, ChungCheongNam-Do (KR); Bo Hyun Lee, ChungCheongNam-Do (KR); Seung Yong Park, ChungCheongNam-Do (KR)

(72) Inventors: BONGMO PARK, ChungCheongNam-Do (KR); Kwang Je Woo, ChungCheongNam-Do (KR); Jun Sung Choi, ChungCheongNam-Do (KR); Bo Hyun Lee, ChungCheongNam-Do (KR); Seung Yong Park, ChungCheongNam-Do (KR)

(73) Assignee: SAMSUNG CORNING PRECISION MATERIALS CO., LTD.

(21) Appl. No.: 13/559,357

(22) Filed: Jul. 26, 2012

(30) Foreign Application Priority Data
Jul. 26, 2011 (KR) 10-2011-0074055

(51) Int. Cl. H01L 21/02

(52) U.S. Cl. 438/455; 257/E21.002

(57) ABSTRACT

A gallium nitride (GaN) bonded substrate and a method of manufacturing a GaN bonded substrate in which a polycrystalline nitride-based substrate is used. The method includes loading a single crystalline GaN substrate and a polycrystalline nitride substrate into a bonder; raising the temperature in the bonder; bonding the single crystalline GaN substrate and the polycrystalline nitride substrate together by pressing the single crystalline GaN substrate and the polycrystalline nitride substrate against each other after the step of raising the temperature; and cooling the resultant bonded substrate.

### CROSS REFERENCE TO RELATED APPLICATION

The present application claims priority from Korean Patent Application Number 10-2011-0074055 filed on Jul. 26, 2011, the entire contents of which application are incorporated herein for all purposes by this reference.

### BACKGROUND OF THE INVENTION

1. Field of the Invention

The present invention relates to a gallium nitride (GaN) bonded substrate and a method of manufacturing a GaN bonded substrate, and more particularly, to a GaN bonded substrate and a method of manufacturing a GaN bonded substrate in which a polycrystalline nitride-based substrate is used.

2. Description of Related Art

In general, gallium nitride (GaN) has characteristics suitable for optical devices and high-temperature and high-power devices, owing to the wide energy band gap, great mutual bonding force between atoms, and high thermal conductivity.

In particular, since GaN has a very large transition energy bandwidth, it can generate light in the range from ultraviolet (UV) to blue rays. This feature makes GaN an essential next-generation photoelectric material that is used for blue laser diodes (LDs), which are used as light sources for next-generation digital versatile discs (DVDs), white light-emitting diodes (LEDs), which are replacing the existing illumination devices, high-temperature and high-power electronic devices, and the like.

Making a device, such as an LED, using GaN involves a process of bonding a grown GaN thin or thick film to a sub-substrate, which acts as a support substrate, a layer transfer process of separating the GaN thin or thick film from the remaining structure except for a partial layer of several micrometers or less, and then a subsequent process such as an epitaxial process.

Accordingly, in the related art, a silicon (Si) substrate has been generally used as a sub-substrate in order to bond a GaN substrate. Although the Si substrate has merits in terms of the cost and large diameter, there are the following problems. Since the coefficient of thermal expansion (CTE) of the Si substrate differs from that of GaN, it is difficult to change the temperature conditions in the bonding process. Consequently, a bonding force is also decreased, and a bonding area is also limited.

In addition, in the epitaxial process in which an LED is fabricated after the bonding process, cracks frequently occur due to the difference in the CTE between the Si substrate and the GaN substrate when raising or lowering the temperature.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a gallium nitride (GaN) bonded substrate and a method of manufacturing a GaN bonded substrate in which the bonding force and bonding area of the GaN bonded substrate are increased, and cracks that occur in an epitaxial process in which GaN light-emitting diodes (LEDs) are fabricated can be reduced.

In an aspect of the present invention, provided is a method of manufacturing a GaN bonded substrate. The method includes the following steps of: loading a single crystalline GaN substrate and a polycrystalline nitride substrate into a bonder; raising the temperature in the bonder; bonding the single crystalline GaN substrate and the polycrystalline nitride substrate together by pressing the single crystalline GaN substrate and the polycrystalline nitride substrate against each other after the step of raising the temperature; and cooling the resultant bonded substrate.

The polycrystalline nitride substrate may be one selected from among a polycrystalline GaN substrate, a polycrystalline indium nitride (InN) substrate and a polycrystalline aluminum nitride (AlN) substrate.

In addition, the step of raising the temperature may raise the temperature to 800° C.

In addition, the step of bonding the single crystalline GaN substrate and the polycrystalline nitride substrate together may press the single crystalline GaN substrate and the polycrystalline nitride substrate under a force of 4000N or greater.

In another aspect of the present invention, provided is a GaN bonded substrate including a polycrystalline GaN substrate; and a single crystalline GaN substrate bonded onto the polycrystalline GaN substrate.

As set forth above, it is possible to increase the bonding force and bonding area of the bonded substrate since the polycrystalline nitride substrate, the coefficient of thermal expansion (CTE) of which is similar to that of GaN, is used in the GaN bonding process.

Furthermore, it is possible to reduce cracks that occur due to the difference in the CTE between the GaN substrate and the sub-substrate in the epitaxial process in which GaN semiconductor LEDs are fabricated.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a schematic flowchart depicting a method of manufacturing a GaN bonded substrate according to an exemplary embodiment of the invention.

### DETAILED DESCRIPTION OF THE INVENTION

Reference will now be made in detail to a GaN bonded substrate and a method of manufacturing a GaN bonded substrate according to the invention, embodiments of which are illustrated in the accompanying drawings and described below.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

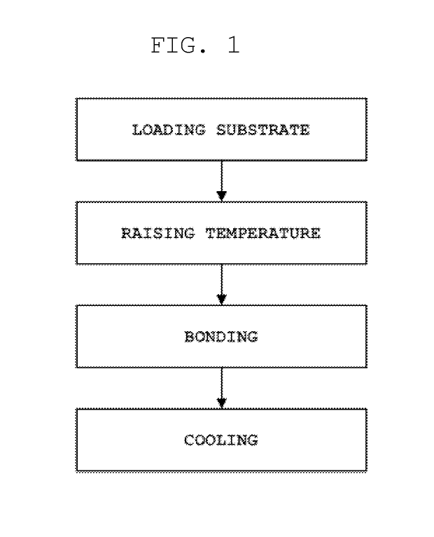

FIG. 1 is a schematic flowchart depicting a method of manufacturing a gallium nitride (GaN) bonded substrate according to an exemplary embodiment of the invention.

Referring to FIG. 1, the method of manufacturing a GaN bonded substrate includes a substrate loading step (first step), a temperature raising step (second step), a bonding step (third step), and a cooling step (fourth step).

In order to manufacture a GaN bonded substrate, first, a single crystalline GaN substrate and a polycrystalline nitride substrate are loaded into a bonder (first step).

The bonder may be a wafer bonder, in which the single crystalline GaN substrate is disposed in an upper press of the bonder and the polycrystalline nitride substrate is disposed in a lower press of the bonder.

Here, the polycrystalline nitride substrate may be a polycrystalline GaN substrate, a polycrystalline indium nitride (InN), or a polycrystalline aluminum nitride (AlN) substrate.

Such a polycrystalline nitride substrate may be manufactured using polycrystalline nitride powder, which is deposited on a reactor, a susceptor, or the like in the process of manufacturing a single crystalline nitride thin or thick film.

In an example, the polycrystalline nitride substrate may be made by collecting polycrystalline GaN powder, which is deposited on the reactor or susceptor in the process of growing the single crystalline GaN thin or thick film, loading the collected polycrystalline GaN powder into a mold, and then sintering the polycrystalline GaN powder in the mold.

Afterwards, the temperature in the bonder is raised (second step). It is preferred that the temperature be raised to 800° C.

When the temperature in the bonder is raised to a predetermined temperature or higher, the single crystalline GaN substrate and the polycrystalline nitride substrate are bonded together by pressing them against each other (third step).

The substrates may be bonded together by pressing both substrates against each other by driving the upper press on which the GaN substrate is disposed and the lower press on which the polycrystalline nitride substrate is disposed.

Here, it is preferred that the bonding be carried out by the pressing under a force of 4000N or greater.

Afterwards, the resultant substrate in which the single GaN substrate is bonded to the polycrystalline nitride substrate is cooled at room temperature (fourth step), thereby completing the manufacture the GaN bonded substrate.

As described above, since the polycrystalline nitride substrate, the coefficient of thermal expansion (CTE) of which is similar to that of single crystal GaN, is used as a sub-substrate in the nitride bonding process, it is possible to increase the bonding force and bonding area of the bonded substrate. Accordingly, this makes it easy to bond a single crystalline GaN substrate having a large diameter of 4 inches or greater to the sub-substrate.

In addition, a GaN semiconductor LED generally includes an N-type semiconductor layer, an active layer and a P-type semiconductor layer, which are sequentially stacked over a substrate. The GaN semiconductor LED also includes a P-type electrode, which is formed on the P-type semiconductor layer, and an N-type electrode, which is exposed because a part of the P-type electrode and a part of the active layer are etched. Here, the P-type semiconductor layer is made of a GaN semiconductor compound that is doped with P-type impurities such as magnesium (Mg), and the N-type semiconductor layer is made of a GaN semiconductor compound that is doped with N-type impurities such as silicon (Si). The P-type and N-type semiconductor layers, which are formed on the upper portion and the lower portion of the active layer, serve to supply current to the active layer so that the GaN semiconductor generates light.

The GaN semiconductor LED is fabricated using an epitaxial process in which the N-type semiconductor layer, the active layer and the P-type semiconductor layer are deposited on a single crystal GaN substrate. Here, crystalline defects, such as cracks, occur owing to the CTE mismatch between the single crystal GaN substrate and the sub-substrate.

However, in the bonded substrate of the invention, since the polycrystalline nitride substrate, the CTE of which is similar to that of the single crystalline GaN substrate, is used as the sub-substrate, crystalline defects such as cracks, which occur in the epitaxial process in which GaN LEDs are fabricated, are reduced, thereby making it possible to fabricate high-quality GaN LEDs.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of manufacturing a gallium nitride bonded substrate, comprising:
loading a single crystalline gallium nitride substrate and a polycrystalline nitride substrate into a bonder;
raising a temperature in the bonder;
after the temperature in the bonder is raised, bonding the single crystalline gallium nitride substrate and the polycrystalline nitride substrate together by pressing the single crystalline gallium nitride substrate and the polycrystalline nitride substrate against each other, thereby producing a bonded substrate; and
cooling the bonded substrate.

2. The method of claim 1, wherein the polycrystalline nitride substrate comprises one selected from the group consisting of a polycrystalline gallium nitride substrate, a polycrystalline indium nitride substrate and a polycrystalline aluminum nitride substrate.

3. The method of claim 1, wherein the temperature in the bonder is raised to 800° C.

4. The method of claim 1, wherein bonding the single crystalline gallium nitride substrate and the polycrystalline nitride substrate together comprises pressing the single crystalline gallium nitride substrate and the polycrystalline nitride substrate under a force of 4000N or greater.
